(19) United States
(12) Patent Application Publication
(10) Pub. No.: US 2014/0308618 A1
(43) Pub. Date: Oct. 16, 2014

(54) Organic Solution for Surface Treatment of Induim Zinc Oxide Substrate and Method of Preparing Display Substrate Using the Same

(71) Applicant: Cheil Industries Inc., Gumi-si (KR)

(72) Inventors: Hyun-Moo CHOI, Uiwang-si (KR); Ji-Hye KIM, Uiwang-si (KR); Kyung-Won AHN, Uiwang-si (KR); A-Rum YU, Uiwang-si (KR); Jae-Bum YIM, Uiwang-si (KR); Hwan-Sung CHEON, Uiwang-si (KR); Gun-Young HEO, Uiwang-si (KR)

(73) Assignee: Cheil Industries Inc., Gumi-si (KR)

(21) Appl. No.: 14/077,785

(22) Filed: Nov. 12, 2013

(30) Foreign Application Priority Data
Apr. 10, 2013 (KR) 10-2013-0039335
Jun. 3, 2013 (KR) 10-2013-0063501

(51) Int. Cl. G03F 7/26

(52) U.S. Cl. CPC G03F 7/26
USPC 430/320; 430/331

(57) ABSTRACT

Disclosed are an organic solution for surface-treating an indium zinc oxide (IZO) substrate that is used for surface treatment of an indium zinc oxide (IZO) substrate, and includes an organic material, and a method of preparing a display substrate using the same.

### CROSS REFERENCE TO RELATED APPLICATIONS

This application claims priority to and the benefit of Korean Patent Application Nos. 10-2013-0039335 and 10-2013-0063501 filed in the Korean Intellectual Property Office on Apr. 10, 2013, and Jun. 3, 2013, respectively, the entire disclosure of each of which is incorporated herein by reference.

### FIELD

An organic solution for surface-treating an indium zinc oxide (IZO) substrate and a method of preparing a display substrate using the same are disclosed.

### BACKGROUND

In general, since a black material is coated on a glass substrate for a display and forms a black pattern without generating residues, this process may be performed without a problem. The black pattern may include a black matrix or a black column spacer.

Recently, there has been increased interest in indium zinc oxide (IZO) as well as indium tin oxide (ITO) as electrodes used for a display panel. Thus, there have been attempts to make a black pattern on these substrates.

### SUMMARY

One embodiment provides an organic solution for surface-treating an indium zinc oxide (IZO) substrate in order to minimize residues during pattern formation of a light-blocking layer.

Another embodiment provides a method of preparing a display substrate using the organic solution for surface-treating the indium zinc oxide (IZO) substrate.

One embodiment provides an organic solution for surface-treating an indium zinc oxide (IZO) substrate that is used for surface treatment of an indium zinc oxide (IZO) substrate, and includes an organic material including nitrilo triacetic acid, hydroxamic acid, thiol, carboxylic acid, alcohol, phosphoric acid, sulfonic acid, or a combination thereof.

The organic solution may further include a solvent, and the solvent may include distilled water, alcohol, N-methylpyrrolidone, dimethylsulfoxide, dimethylformamide, or a combination thereof.

The organic material may be included in an amount of about 1 to about 10 wt % based on total amount of the organic solution.

Another embodiment provides a method of preparing a display substrate that includes surface-treating an indium zinc oxide (IZO) substrate with an organic material; and coating a photosensitive resin composition on the IZO substrate surface-treated with the organic material, followed by prebaking, exposing, and developing the same, to form a light-blocking layer, wherein the organic material includes nitrilo triacetic acid, hydroxamic acid, thiol, carboxylic acid, alcohol, phosphoric acid, sulfonic acid, or a combination thereof.

The IZO substrate may be surface-treated by dipping the IZO substrate in an organic solution including the organic material.

The photosensitive resin composition may include a binder resin, a photopolymerizable monomer, a photopolymerization initiator, a colorant, and a solvent.

Other embodiments are included in the following detailed description.

A pattern of a light-blocking layer with minimum or no residues on an indium zinc oxide (IZO) substrate may be realized.

### BRIEF DESCRIPTION OF THE DRAWINGS

FIGS. 1 to 4 are optical microscope photographs showing residue images of display substrates according to Example 1 and Comparative Example 1 to 3, respectively.

### DETAILED DESCRIPTION

The present invention will be described more fully hereinafter in the following detailed description of the invention, in which some but not all embodiments of the invention are described. Indeed, this invention may be embodied in many different forms and should not be construed as limited to the embodiments set forth herein; rather, these embodiments are provided so that this disclosure will satisfy applicable legal requirements.

One embodiment provides an organic solution for surface treatment of an IZO substrate used for surface treatment of indium zinc oxide (IZO) substrate.

The organic solution includes an organic material. Examples of the organic material may include without limitation nitrilo triacetic acid, hydroxamic acid, thiols, carboxylic acids, alcohols, phosphoric acid, sulfonic acid, and the like, and combinations thereof. In exemplary embodiments, nitrilo triacetic acid may be used.

When the surface of the IZO substrate is treated with the organic solution including the organic material, residues of a light-blocking layer material may be minimized due to an interaction of the organic material with a zinc metal on the IZO substrate during formation of a light-blocking layer on an IZO substrate in a subsequent process.

The organic solution may further include a solvent. Examples of the solvent may include without limitation distilled water, alcohols, N-methylpyrrolidone, dimethylsulfoxide, dimethylformamide, and the like, and combinations thereof. Examples of the alcohol may include without limitation primary alcohols, secondary alcohols, tertiary alcohols, and the like, and combinations thereof.

The organic solution may include the organic material in an amount of about 1 to about 10 wt %, for example about 3 to about 7 wt %, based on total amount (100 wt %) of the organic solution. In some embodiments, the organic solution may include the organic material in an amount of about 1, 2, 3, 4, 5, 6, 7, 8, 9, or 10 wt %. Further, according to some embodiments of the present invention, the amount of the organic material can be in a range from about any of the foregoing amounts to about any other of the foregoing amounts.

When the organic material is included in an amount within the above range, the organic material may effectively interact on the surface of an IZO substrate and minimize residues of a light-blocking layer material during formation of a light-blocking layer.

According to another embodiment, the organic solution may be used to form a light-blocking layer on a surface-treated IZO substrate, manufacturing a display substrate.

Specifically, the display substrate may be manufactured by treating the surface of an IZO substrate with the organic material and forming a light-blocking layer on the IZO substrate that is surface-treated with the organic material.

When the surface of an IZO substrate is pre-treated with an organic material before forming a light-blocking layer, the organic material can interact with a zinc metal on the IZO substrate and thus, may minimize residues of the light-blocking layer material on the surface of the IZO substrate.

According to one embodiment, a light-blocking layer is formed on an IZO substrate to manufacture a display substrate. In contrast, an indium tin oxide (ITO) substrate has no high close-contacting (adhesive) force with a light-blocking layer material and generates almost no residue of a light-blocking layer material. Unlike the ITO substrate, the IZO substrate has very high close-contacting force with a light-blocking layer material and generates a residue, and thus, when a light-blocking layer is formed after pretreating the organic material on the surface of the IZO substrate, residues of the light-blocking layer material may be minimized.

The treatment of the surface of the IZO substrate with an organic material may be performed by dipping the IZO substrate in the organic solution including the organic material and the solvent.

Subsequently, the light-blocking layer can be formed by coating, prebaking, exposing, and developing a photosensitive resin composition on the IZO substrate that is surface-treated with the organic material.

The photosensitive resin composition may include a binder resin, a photopolymerizable monomer, a photopolymerization initiator, a colorant, and a solvent.

Hereinafter, each component of the photosensitive resin composition is described.

Examples of the binder resin may include without limitation cardo-based resins, acrylic-based resins, and the like, and combinations thereof.

A weight average molecular weight of the cardo-based resin measured by gel permeation chromatography (GPC) may range from about 1,000 to about 20,000 g/mol, for example about 1,500 to about 8,000 g/mol. When the cardo-based resin has a weight average molecular weight within the above range, excellent patterning capability and developability may be provided during preparation of a light-blocking layer.

Specific examples of the acrylic-based resin may include without limitation a methacrylic acid/benzylmethacrylate copolymer, a methacrylic acid/benzylmethacrylate/styrene copolymer, a methacrylic acid/benzyl methacrylate/2-hydroxyethylmethacrylate copolymer, a methacrylic acid/benzyl methacrylate/styrene/2-hydroxyethylmethacrylate copolymer, and the like. They may be used singularly or as a mixture of two or more.

A weight average molecular weight of the acrylic-based resin may range from about 3,000 to about 150,000 g/mol, for example about 5,000 to about 50,000 g/mol, and as another example about 5,000 to about 30,000 g/mol. When the acrylic-based resin has a weight average molecular weight within the above range, the photosensitive resin composition can have good physical and chemical properties, appropriate viscosity, and close contacting (adhesive) properties with a substrate during preparation of a light-blocking layer.

The photosensitive resin composition may include the binder resin in an amount of about 5 to about 50 wt %, for example about 10 to about 30 wt % based on total amount (100 wt %) of the photosensitive resin composition. In some embodiments, the photosensitive resin composition may include the binder resin in an amount of about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 wt %. Further, according to some embodiments of the present invention, the amount of the binder resin can be in a range from about any of the foregoing amounts to about any other of the foregoing amounts.

When the binder resin is included in an amount within the above range, patterning capability, processability, and developability can be improved during preparation of a light-blocking layer due to appropriate viscosity.

The photopolymerizable monomer may include a monofunctional and/or multi-functional ester of (meth)acrylic acid having at least one ethylenic unsaturated double bond.

The photopolymerizable monomer causes sufficient polymerization at exposure during pattern forming processes to form patterns that can have excellent heat resistance, light resistance, and chemical resistance, due to the ethylenic unsaturated double bond.

Specific examples of the photopolymerizable monomer may include without limitation ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether(meth)acrylate, trimethylol propane tri(meth)acrylate, tris(meth)acryloyloxyethyl phosphate, novolacepoxy(meth)acrylate, and the like, and combinations thereof. The photopolymerizable monomer may be treated with acid anhydride to improve developability.

The photosensitive resin composition may include the photopolymerizable monomer in an amount of about 1 to about 20 wt %, for example about 1 to about 15 wt %, based on total amount (100 wt %) of the photosensitive resin composition. In some embodiments, the photosensitive resin composition may include the photopolymerizable monomer in an amount of about 1, 2, 3, 4, 5, 6, 7, 8, 9, 10, 11, 12, 13, 14, 15, 16, 17, 18, 19, or 20 wt %. Further, according to some embodiments of the present invention, the amount of the photopolymerizable monomer can be in a range from about any of the foregoing amounts to about any other of the foregoing amounts.

When the photopolymerizable monomer is included in an amount within the above range, curing at exposure during pattern forming processes can be sufficiently performed, and compatibility with a binder may be improved due to excellent sensitivity under oxygen.

Examples of the photopolymerization initiator may include without limitation acetophenone-based compounds, benzophenone-based compounds, thioxanthone-based compounds, benzoin-based compounds, triazine-based compounds, oxime-based compounds, and the like, and combinations thereof.

Examples of the acetophenone-based compound may include without limitation 2,2′-diethoxyacetophenone, 2,2′-dibutoxyacetophenone, 2-hydroxy-2-methylpropinophenone, p-t-butyltrichloroacetophenone, p-t-butyldichloroacetophenone, 4-chloroacetophenone, 2,2′-dichloro-4-phenoxyacetophenone, 2-methyl-1-(4-(methylthio)phenyl)-2-morpholinopropan-1-one, 2-benzyl-2-dimethylamino-1-(4-morpholinophenyl)-butan-1-one, and the like, and combinations thereof.

Examples of the benzophenone-based compound may include without limitation benzophenone, benzoyl benzoic acid, benzoyl benzoic acid methyl, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like, and combinations thereof.

Examples of the thioxanthone-based compound may include without limitation thioxanthone, 2-methylthioxanthone, isopropyl thioxanthone, 2,4-diethyl thioxanthone, 2,4-diisopropyl thioxanthone, 2-chlorothioxanthone, and the like, and combinations thereof.

Examples of the benzoin-based compound may include without limitation benzoin, benzoin methyl ether, benzoin ethyl ether, benzoin isopropyl ether, benzoin isobutyl ether, benzyldimethylketal, and the like, and combinations thereof.

Examples of the triazine-based compound may include without limitation 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphtho1-yl)-4,6-bis(trichloromethyl)-s-triazine, 2-(4-methoxynaphtho1-yl)-4,6-bis(trichloromethyl)-s-triazine, 2-4-tri chloromethyl(piperonyl)-6-triazine, 2-4-trichloromethyl (4′-methoxystyryl)-6-triazine, and the like, and combinations thereof.

Examples of the oxime-based compound may include without limitation O-acyloxime-based compounds, 2-(O-benzoyloxime)-1-[4-(phenylthio)phenyl]-1,2-octandione, 1-(O-acetyloxime)-1-[9-ethyl-6-(2-methylbenzoyl)-9H-carbazol-3-yl]ethanone, 0-ethoxycarbonyl-α-oxyamino-1-phenylpropan-1-one, and the like, and combinations thereof. Specific examples of the O-acyloxime-based compound may include without limitation 1,2-octandione, 2-dimethylamino-2-(4-methylbenzyl)-1-(4-morpholin-4-yl-phenyl)butan-1-one, 1-(4-phenyl sulphanyl phenyl)butane-1,2-dione 2-oxime-O-benzoate, 1-(4-phenyl sulphanyl phenyl)-octane-1,2-dione 2-oxime-O-benzoate, 1-(4-phenyl sulphanyl phenyl)-octan-1-oneoxime-O-acetate, and 1-(4-phenyl sulphanyl phenyl)-butan-1-oneoxime-O-acetate, and the like, and combinations thereof.

Other examples of the photopolymerization initiator may further include without limitation carbazole-based compounds, diketone-based compounds, sulfonium borate-based compounds, diazo-based compounds, biimidazole-based compounds, and the like, and combinations thereof.

The photosensitive resin composition may include the photopolymerization initiator in an amount of about 0.1 to about 20 wt %, for example about 1 to about 10 wt %, based on total amount (100 wt %) of the photosensitive resin composition. In some embodiments, the photosensitive resin composition may include the photopolymerization initiator in an amount of about 0.1, 0.2, 0.3, 0.4, 0.5, 0.6, 0.7, 0.8, 0.9, 1, 2, 3, 4, 5, 6, 7, 8, 9, 10, 11, 12, 13, 14, 15, 16, 17, 18, 19, or 20 wt %. Further, according to some embodiments of the present invention, the amount of the photopolymerization initiator can be in a range from about any of the foregoing amounts to about any other of the foregoing amounts.

When the photopolymerization initiator is included in an amount within the above range, sufficient photopolymerization can be performed at exposure during pattern forming process of a light-blocking layer to obtain excellent sensitivity, linearity of a pattern, dissolution for a solvent, and storage stability with minimal or no deterioration of transmittance due to residual non-reacting initiators remaining after photopolymerization.

The colorant may include a pigment, a dye, or a combination thereof.

The pigment may include an organic pigment, an inorganic pigment, or a combination thereof. The organic pigment and the inorganic pigment may be mixed to realize a high optical density.

The organic pigment may include a black organic pigment. The black organic pigment has insulation properties.

Examples of the black organic pigment may include without limitation perylene black, cyanine black, and the like, and may be used singularly or in a combination of two or more.

The black organic pigment may be a mixture of two or more kinds of organic pigments to show a black color. Combinations of any pigment showing a black color by mixing in a color coordinate pigment may be used, and specifically blackening combinations of at least two selected from a red pigment, a blue pigment, a green pigment, a violet-based pigment, a yellow-based pigment, a cyanine-based pigment, and a magenta-based may be used. For example, a blackening mixture of a red-based pigment, a blue-based pigment, and a green-based pigment may be used, or a blackening mixture of a green pigment and a violet-based pigment may be used.

Examples of the red-based pigment may include without limitation perylene-based pigments, anthraquinone-based pigments, dianthraquinone-based pigments, azo-based pigments, diazo-based pigments, quinacridone-based pigments, anthracene-based pigments, and the like, and combinations thereof. Specific examples of the red-based pigment may include without limitation perylene pigments, quinacridone pigments, naphthol AS, sicomin pigments, anthraquinones (sudan I, II, III, R), dianthraquinonylate, bis azo, benzopyrane, and the like, and combinations thereof.

Examples of the blue-based pigment may include without limitation metal phthalocyanine-based pigments, indanthone-based pigments, indophenol-based pigments, and the like, and combinations thereof. Specific examples of the blue-based pigment may include without limitation phthalocyanine metal complexes such as copper phthalocyanine, chloro copper phthalocyanine, chloro aluminum phthalocyanine, titanyl phthalocyanine, vanadic acid phthalocyanine, magnesium phthalocyanine, zinc phthalocyanine, iron phthalocyanine, cobalt phthalocyanine, and the like, and combinations thereof.

Examples of the green-based pigment may include without limitation halogenated phthalocyanine-based pigments and combinations thereof. Specific examples of the green pigment may include without limitation polychloro copper phthalocyanine, polychloro bromo phthalocyanine, and the like, and combinations thereof.

Examples of the violet-based pigment may include without limitation dioxazine violet, first violet B, methyl violet, indanthrone brilliant violet, and the like, and combinations thereof.

Examples of the yellow-based pigment may include without limitation tetra chloro isoindolinone-based pigments, hansa-based pigments, benzidine yellow-based pigments, azo-based pigments, and the like, and combinations thereof. Specific examples of yellow-based pigments may include without limitation hansa yellows (10G, 5G, 3G, G, GR, A, RN, R), benzidines (G, GR), chrome yellow, permanent yellows (FGL, H10G, HR), anthracene, and the like, and combinations thereof.

Examples of the cyanine-based pigment may include without limitation non-metal phthalocyanines, merocyanine, and the like, and combinations thereof.

Examples of the magenta-based pigment may include without limitation dimethyl quinacridone, thio indigo, and the like, and combinations thereof.

Examples of the inorganic pigment may include without limitation carbon black, chromium oxide, iron oxide, titan black, titanium carbide, aniline black, and the like. Such an inorganic pigment can have high resistance characteristics, and one or more kinds may be used singularly and as a mixture thereof.

The photosensitive resin composition may further include a dispersing agent in order to improve dispersion of the pigment.

The pigment may be surface-pretreated with a dispersing agent, or the pigment and dispersing agent may be added together during preparation of the photosensitive resin composition.

Examples of the dye may include without limitation triphenylmethane-based dyes, anthraquinone-based dyes, azo-based dyes, and the like, and combinations thereof. In exemplary embodiments, a mixture of the triphenylmethane-based dye, and at least one of the anthraquinone-based and azo-based dye may be used.

The photosensitive resin composition may include the colorant in an amount of about 1 to about 40 wt %, for example about 5 to about 30 wt %, based on the total amount (100 wt %) of the photosensitive resin composition. In some embodiments, the photosensitive resin composition may include the colorant in an amount of about 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, or 40 wt %. Further, according to some embodiments of the present invention, the amount of the colorant can be in a range from about any of the foregoing amounts to about any other of the foregoing amounts.

When the colorant is included in an amount within the above range, insulating properties may be improved, and high optical density, and improved processability such as developability, and the like may be provided.

Examples of the solvent may include without limitation alcohols such as methanol, ethanol, and the like; ethers such as dichloroethyl ether, n-butyl ether, diisoamyl ether, methylphenyl ether, tetrahydrofuran, and the like; glycol ethers such as ethylene glycol methylether, ethylene glycol ethylether, propylene glycol methylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol methylether acetate, propylene glycol propylether acetate, and the like; aromatic hydrocarbons such as toluene, xylene, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate alkyl esters such as methyl lactate, ethyl lactate, and the like; alkyl hydroxy acetate ester such as methyl hydroxyacetate, ethyl hydroxyacetate, butyl hydroxyacetate, and the like; alkoxyalkyl acetate esters such as methoxymethyl acetate, methoxyethyl acetate, methoxybutyl acetate, ethoxymethyl acetate, ethoxyethyl acetate, and the like; alkyl 3-hydroxypropionate esters such as methyl 3-hydroxypropionate, ethyl 3-hydroxypropionate, and the like; alkyl 2-hydroxypropionate esters such as methyl 2-hydroxypropionate, ethyl 2-hydroxypropionate, propyl 2-hydroxypropionate, and the like; alkyl 2-alkoxypropionate esters such as methyl 2-methoxypropionate, ethyl 2-methoxypropionate, ethyl 2-ethoxypropionate, methyl 2-ethoxypropionate, and the like; alkyl 2-hydroxy-2-methylpropionate esters such as methyl 2-hydroxy-2-methylpropionate, ethyl 2-hydroxy-2-methylpropionate, and the like; alkyl 2-alkoxy-2-methylpropionate esters such as methyl 2-methoxy-2-methylpropionate, ethyl 2-ethoxy-2-methylpropionate, and the like; esters such as 2-hydroxyethyl propionate, 2-hydroxy-2-methylethyl propionate, hydroxyethyl acetate, methyl 2-hydroxy-3-methylbutanoate, and the like; ketonate esters such as ethyl pyruvate, and the like, and combinations thereof. Additionally, the following solvents may be also used: N-methylformamide, N,N-dimethylformamide, N-methylformanilide, N-methylacetamide, N,N-dimethylacetamide, N-methylpyrrolidone, dimethylsulfoxide, benzylethylether, dihexylether, acethylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, and the like, and combinations thereof. These solvents may be used singularly or as a mixture of two or more.

Considering miscibility and reactivity, the solvent can include glycol ethers such as ethylene glycol monoethyl ether, and the like; ethylene glycol alkylether acetates such as ethyl cellosolve acetate, and the like; esters such as 2-hydroxy ethyl propionate, and the like; diethylene glycols such as diethylene glycol monomethylether, and the like; propylene glycol alkylether acetates such as propylene glycol methylether acetate, propylene glycol propylether acetate, and the like, and combinations thereof.

The photosensitive resin composition can include the solvent in a balance amount, for example about 20 to about 90 wt %, based on the total amount (100 wt %) of the photosensitive resin composition. In some embodiments, the photosensitive resin composition may include the solvent in an amount of about 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, or 90 wt %. Further, according to some embodiments of the present invention, the amount of the solvent can be in a range from about any of the foregoing amounts to about any other of the foregoing amounts.

When the solvent is included in an amount within the above range, the photosensitive resin composition can have good coating properties and can maintain excellent flatness of a film having a thickness of about 2 μm or more.

The photosensitive resin composition may further include one or more other additives such as but not limited to malonic acid; 3-amino-1,2-propanediol; a silane-based coupling agent including a vinyl group or a (meth)acryloxy group; a leveling agent; a fluorine-based surfactant; a radical polymerization initiator, and the like, and combinations thereof, in order to prevent stains or spots during the coating, to adjust leveling, and/or to prevent pattern residue due to non-development.

Examples of the silane-based coupling agent may include without limitation trimethoxysilyl benzoic acid, γ-methacryl oxypropyl trimethoxysilane, vinyl triacetoxysilane, vinyl trimethoxysilane, γ-iso cyanate propyl triethoxysilane, γ-glycidoxy propyl trimethoxysilane, β-(3,4-epoxycyclohexyl)ethyltrimethoxysilane, and the like. These may be used singularly or in a mixture of two or more.

Examples of the fluorine-based surfactant may include without limitation commercial products, for example BM-1000®, and BM-1100® (BM Chemie Inc.); MEGAFACE F 142D®, F 172®, F 173®, and F 183® DAINIPPON INK KAGAKU KOGYO CO., LTD.); FULORAD FC-135®, FULORAD FC-170C®, FULORAD FC-430®, and FULORAD FC-431® (SUMITOMO 3M CO., LTD.); SURFLON S-112®, SURFLON S-113®, SURFLON S-131®, SURFLON S-141®, and SURFLON S-145® (ASAHI GLASS CO., LTD.); and SH-28PA®, SH-190®, SH-193®, SZ-6032®, and SF-8428®, and the like (TORAY SILICONE CO., LTD.), and combinations thereof.

The amount of the additive(s) may be easily adjusted depending on desired properties.

The photosensitive resin composition can be applied, prebaked, exposed, and developed to form the light-blocking layer according to the following method.

The above-described photosensitive resin composition can be coated to have a desired thickness, for example, a thickness ranging from about 0.5 to about 25 μm, on a substrate which undergoes a predetermined pretreatment, using a spin or slit coating method, a roll coating method, a screen-printing method, an applicator method, and the like. Then, the coated substrate can be heated at a temperature ranging from about 70 to about 110° C. for about 1 to about 10 minutes to remove a solvent.

The resultant film can be radiated by an active ray of about 190 to about 500 nm after putting a mask with a predetermined shape to form a desired pattern. The radiation can be performed by using a light source such as a mercury lamp with a low pressure, a high pressure, or an ultrahigh pressure, a metal halide lamp, an argon gas laser, and the like. An X ray, an electron beam, and the like may be also used.

The exposure process can use, for example, a light dose of about 500 mJ/cm² or less (with an about 365 nm sensor) when a high pressure mercury lamp is used. However, the light dose may vary depending on kinds of each component of the photosensitive resin composition, its combination ratio, and a dry film thickness, and can be readily determined by the skilled artisan.

After the exposure process, an alkali aqueous solution can be used to develop the exposed film by dissolving and removing an unnecessary part except the exposed part, forming an image pattern.

The developed image pattern may be heated again or radiated by an active ray and the like for curing, in order to accomplish excellent quality in terms of heat resistance, photo resistance, close contacting (adhesive) properties, crack-resistance, chemical resistance, high strength, storage stability, and the like.

Therefore, the photosensitive resin composition may bring about excellent close contacting property and optical density required for a light blocking layer.

The light-blocking layer may be a black matrix, a black column spacer, or a combination thereof for a display.

Hereinafter, the present invention is illustrated in more detail with reference to examples. These examples, however, are not in any sense to be interpreted as limiting the scope of the invention.

### Example 1

An IZO jumbo glass deposited with indium zinc oxide (IZO) (Sumitomo Corporation Kyushu Co., Ltd.) is cut into a size of 10 cm*10 cm by using a glass cutter. Subsequently, the IZO jumbo glass is dipped in a 100 cm*100 cm container containing 20 ml of an organic solution (DECONEX, DECONEX 16 PLUS) for about 5 minutes, cleaned with distilled water, and dried for greater than or equal to 2 hours in a 100° C. oven. The dried IZO substrate is spin-coated with about 2 ml of a black matrix chemical liquid (CR-BK0951L, Cheil Industries Inc.) and prebaked at 100° C. for about 2 minutes. Subsequently, the baked IZO substrate is exposed under an exposure dose condition of 90 mJ and then developed with a 1% KOH solution for about 80 seconds, manufacturing a display substrate including a light-blocking layer on the IZO substrate.

### Comparative Example 1

A display substrate including a light-blocking layer on an IZO substrate is manufactured according to the same method as Example 1 except for using 100 ml of triple distilled water instead of 20 ml of the organic solution (DECONEX 16 PLUS).

### Comparative Example 2

A display substrate including a light-blocking layer on an IZO substrate is manufactured according to the same method as Example 1 except for using 100 ml of a 1% KOH developing solution instead of 20 ml of the organic solution (DECONEX 16 PLUS).

### Comparative Example 3

A display substrate including a light-blocking layer on an IZO substrate is manufactured according to the same method as Example 1 except for cleaning the IZO jumbo glass with 100 ml of triple distilled water by using 100 ml of a 1% KOH developing solution instead of 20 ml of the organic solution (DECONEX 16 PLUS) and performing an ultrasonic wave pulverization for 5 minutes by using a sonicator.

### Evaluation 1: Residue Measurement

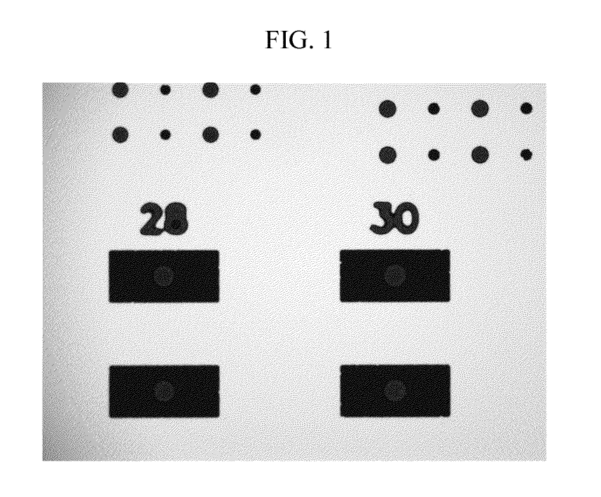

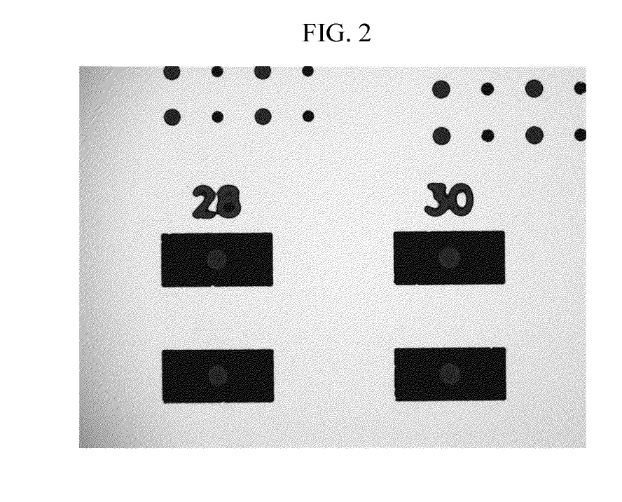

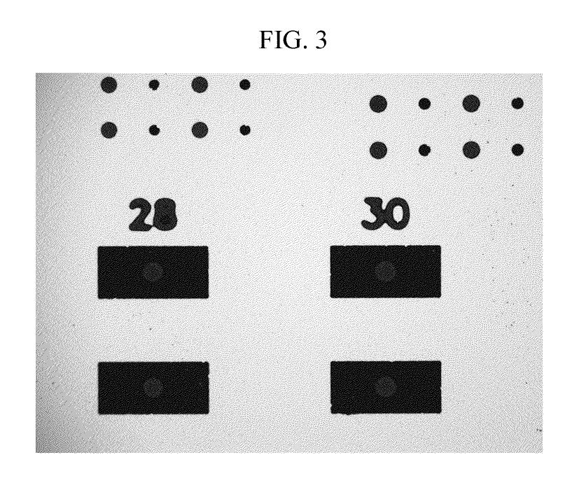

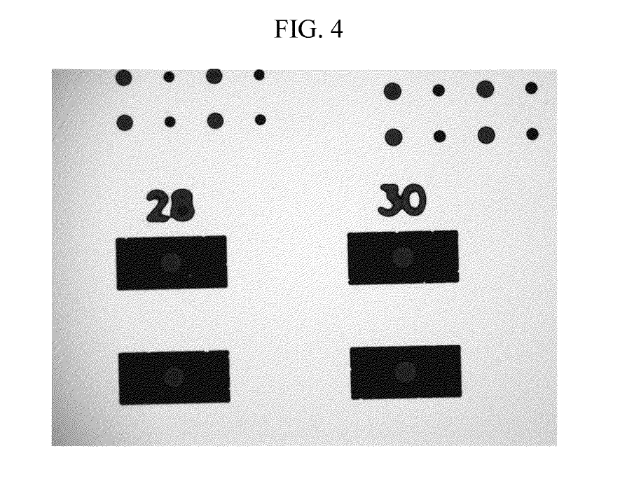

The display substrates according to Example 1 and Comparative Examples 1 to 3 are examined with an optical microscope to check if residues are generated, and the results are provided in FIGS. 1 to 4.

FIGS. 1 to 4 are optical microscope photographs showing residue images of display substrates according to Example 1 and Comparative Example 1 to 3, respectively.

Referring to FIGS. 1 to 4, the display substrate manufactured by pre-treating an organic material on the surface of an IZO substrate according to Example 1 and specifically, a light-blocking layer formed on the IZO substrate exhibits almost no residue generated on the surface compared with the display substrates according to Comparative Examples 1 to 3.

Many modifications and other embodiments of the invention will come to mind to one skilled in the art to which this invention pertains having the benefit of the teachings presented in the foregoing descriptions. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation, the scope of the invention being defined in the claims.

What is claimed is:

1. An organic solution for surface-treating an indium zinc oxide (IZO) substrate, wherein the organic solution is used for surface treatment of an indium zinc oxide (IZO) substrate, comprising an organic material including nitrilo triacetic acid, hydroxamic acid, thiol, carboxylic acid, alcohol, phosphoric acid, sulfonic acid, or a combination thereof.

2. The organic solution of claim 1, wherein the organic solution further comprises a solvent comprising distilled water, alcohol, N-methylpyrrolidone, dimethylsulfoxide, dimethylformamide, or a combination thereof.

3. The organic solution of claim 2, comprising the organic material in an amount of about 1 to about 10 wt % based on total amount of the organic solution.

4. A method of preparing a display substrate, comprising
surface-treating an indium zinc oxide (IZO) substrate with an organic material; and
coating a photosensitive resin composition on the IZO substrate surface-treated with the organic material, followed by prebaking, exposing, and developing the same, to form a light-blocking layer,
wherein the organic material comprises nitrilo triacetic acid, hydroxamic acid, thiol, carboxylic acid, alcohol, phosphoric acid, sulfonic acid, or a combination thereof.

5. The method of claim 4, wherein the IZO substrate is surface-treated by dipping the IZO substrate in an organic solution including the organic material.

6. The method of claim 5, wherein the organic solution further comprises a solvent comprising distilled water, alcohol, N-methylpyrrolidone, dimethylsulfoxide, dimethylformamide, or a combination thereof.

7. The method of claim 6, wherein the organic solution comprises the organic material in an amount of about 1 to about 10 wt % based on the total amount of the organic solution.

8. The method of claim 4, wherein the photosensitive resin composition comprises a binder resin, a photopolymerizable monomer, a photopolymerization initiator, a colorant, and a solvent.
